(19) United States
(12) Patent Application Publication
(10) Pub. No.: US 2026/0052741 A1
(43) Pub. Date: Feb. 19, 2026

(54) MOS TRANSISTOR AND METHOD OF MANUFACTURING THE SAME

(71) Applicants: DENSO CORPORATION, Kariya-city (JP); TOYOTA JIDOSHA KABUSHIKI KAISHA, Toyota-shi (JP); MIRISE Technologies Corporation, Nisshin-shi (JP)

(72) Inventor: Hidemoto TOMITA, Nisshin-shi (JP)

(21) Appl. No.: 19/175,087

(22) Filed: Apr. 10, 2025

(30) Foreign Application Priority Data
Aug. 13, 2024 (JP) 2024-134915

(51) Int. Cl. H10D 62/10; H10D 30/01; H10D 30/66; H10D 62/00; H10D 62/832

(52) U.S. Cl. CPC H10D 62/111; H10D 30/0297; H10D 30/668; H10D 62/054; H10D 62/8325

(57) ABSTRACT

A MOS transistor has a gate insulating film and a gate electrode disposed in a trench. A semiconductor substrate has: a bottom p-type layer in contact with the gate insulating film at a bottom surface of the trench; an intermediate n-type layer disposed within an interval between the bottom p-type layers; and a superjunction layer disposed below the bottom p-type layer. A p-type column layer of the superjunction layer is in contact with the intermediate n-type layer from a lower side. An n-type column layer of the superjunction layer is in contact with the bottom p-type layer and the intermediate n-type layers on both sides of the bottom p-type layer from a lower side.

### CROSS REFERENCE TO RELATED APPLICATION

This application is based on Japanese Patent Application No. 2024-134915 filed on Aug. 13, 2024, the disclosure of which is incorporated herein by reference.

### TECHNICAL FIELD

The present disclosure relates to a MOS transistor and a method of manufacturing the MOS transistor.

### BACKGROUND

A trench gate type MOS transistor is provided with a bottom p-type layer in contact with a gate insulating film at a bottom of a trench as a gate bottom protection region. The bottom p-type layer can suppress electric field concentration on the gate insulating film in the trench.

### SUMMARY

According to an aspect of the present disclosure, a MOS transistor includes: a semiconductor substrate having trenches in an upper surface, and a gate insulating film and a gate electrode disposed in each of the trenches. The semiconductor substrate has: bottom p-type layers arranged in a predetermined direction intersecting each of the trenches and in contact with the gate insulating film at a bottom surface of the trench; intermediate n-type layers respectively arranged within intervals of the bottom p-type layers; and a superjunction layer arranged below the bottom p-type layers. The superjunction layer has p-type column layers and n-type column layers alternately arranged in the predetermined direction. The n-type impurity concentration of the intermediate n-type layer is higher than the n-type impurity concentration of the n-type column layer. Each of the p-type column layers is in contact with the intermediate n-type layer from a lower side. Each of the n-type column layers is in contact with the bottom p-type layer and the intermediate n-type layers on both sides of the bottom p-type layer from a lower side.

According to another aspect of the present disclosure, a method of manufacturing a MOS transistor includes: forming grooves at interval in a predetermined direction on an upper surface of a semiconductor substrate from which a reference n-type layer is exposed; implanting a p-type impurity into the upper surface and a bottom of each of the grooves to form a bottom p-type layer in an area exposed at the upper surface and a p-type column layer in an area exposed at the bottom of each of the grooves; etching a side surface and a bottom surface of each of the grooves where the p-type column layer is located at the bottom; epitaxially growing an intermediate n-type layer having an n-type impurity concentration higher than that of the reference n-type layer on the upper surface such that each of the grooves is filled with the intermediate n-type layer; forming trenches at interval in the predetermined direction on the upper surface of the semiconductor substrate such that the bottom p-type layer is exposed at a bottom surface of each of the trenches; and forming a gate insulating film and a gate electrode in each of the trenches.

### BRIEF DESCRIPTION OF DRAWINGS

FIG. 1 is a cross-sectional view of a MOS transistor according to an embodiment.

FIG. 2 is a cross-sectional view of a MOS transistor of a comparative example.

FIGS. 3A and 3B are explanatory diagrams of a manufacturing process of the MOS transistor.

FIGS. 4A to 4C are explanatory diagrams of a manufacturing process of the MOS transistor.

FIGS. 5A to 5E are explanatory diagrams of a manufacturing process of the MOS transistor.

### DESCRIPTION OF EMBODIMENTS

A trench gate type MOS transistor is provided with a bottom p-type layer in contact with a gate insulating film at a bottom of a trench as a gate bottom protection region. The bottom p-type layer can suppress electric field concentration on the gate insulating film in the trench. An intermediate n-type layer, as a current spreading layer, is provided around each bottom p-type layer. The intermediate n-type layer has a higher n-type impurity concentration than a drift layer located below the intermediate n-type layer. The intermediate n-type layer is disposed in the interval between the bottom p-type layers. The intermediate n-type layer is located within a range larger than each of the bottom p-type layers in an up-down direction, and is in contact with the lower surface of each of the bottom p-type layers. The intermediate n-type layer reduces the resistance of the current path, thereby reducing the on-resistance of the MOS transistor.

As described above, the on-resistance is reduced by the intermediate n-type layer. However, the current is diffused by the intermediate n-type layer, so that the current flows in a wide range within the drift layer below the intermediate n-type layer. Therefore, since the saturation current is high when an overvoltage is applied to the MOS transistor, the short circuit resistance of the MOS transistor is low. This specification proposes a MOS transistor having an intermediate n-type layer to reduce the saturation current.

According to an aspect of the present disclosure, a MOS transistor includes: a semiconductor substrate having trenches formed in an upper surface, and a gate insulating film and a gate electrode disposed in each of the trenches. The semiconductor substrate has: bottom p-type layers arranged at interval along a predetermined direction intersecting each of the trenches and in contact with the gate insulating film at the bottom surface of the corresponding trench; intermediate n-type layers arranged within the corresponding intervals; and a superjunction layer arranged below the bottom p-type layers. The superjunction layer has p-type column layers and n-type column layers alternately arranged along the predetermined direction. The n-type impurity concentration of the intermediate n-type layer is higher than the n-type impurity concentration of the n-type column layer. Each of the p-type column layers is in contact with the intermediate n-type layer from a lower side. Each of the n-type column layers is in contact with the bottom p-type layer and the intermediate n-type layers on both sides of the bottom p-type layer from a lower side.

In the MOS transistor, the superjunction layer is provided below the bottom p-type layer. When the MOS transistor is turned on, electrons that have passed through the channel flow to the n-type column layer of the superjunction layer via the intermediate n-type layer. Since the p-type column layer is in contact with the intermediate n-type layer from the lower side, electrons do not flow from the intermediate n-type layer to the superjunction layer within the area where the p-type column layer is provided. Since the n-type column layer is in contact with the bottom p-type layer from the lower side, electrons do not flow into the n-type column layer from the upper side within the area where the bottom p-type layer exists. For this reason, the region through which electrons flow from the intermediate n-type layer to the n-type column layer is limited to the region between the p-type column layer and the bottom p-type layer in the lateral direction (i.e., the region where the intermediate n-type layer and the n-type column layer are in direct contact with each other). In this way, the area through which the current flows is restricted, thereby reducing the saturation current.

According to another aspect of the present disclosure, a method of manufacturing a MOS transistor includes: forming grooves at interval in a predetermined direction on an upper surface of a semiconductor substrate from which a reference n-type layer is exposed; implanting a p-type impurity into the upper surface and a bottom of each of the grooves to form a bottom p-type layer in an area exposed at the upper surface and a p-type column layer in an area exposed at the bottom of each of the grooves; etching a side surface and a bottom surface of each of the grooves where the p-type column layer is located at the bottom; epitaxially growing an intermediate n-type layer having an n-type impurity concentration higher than that of the reference n-type layer on the upper surface so that each of the grooves is filled with the intermediate n-type layer; forming trenches at interval in the predetermined direction on the upper surface of the semiconductor substrate so that the bottom p-type layer is exposed at a bottom surface of each of the trenches; and forming a gate insulating film and a gate electrode in each of the trenches.

In this manufacturing method, after forming the grooves in the upper surface where the reference n-type layer is exposed, the bottom p-type layer and the p-type column layer are formed by implanting the p-type impurity. The reference n-type layer remaining between the p-type column layers becomes the n-type column layer. After etching the grooves, the intermediate n-type layer is epitaxially grown to fill the grooves. When the intermediate n-type layer is formed in this manner, the intermediate n-type layer is in contact with the p-type column layer at the center of the groove, and in contact with the n-type column layers on both sides of the p-type column layer within the groove. Next, the trenches are formed in the upper surface of the semiconductor substrate so that the bottom p-type layer is exposed at the bottom of each of the trenches. Then, the gate insulating film and the gate electrode are formed in the trenches. By forming the MOS transistor in this manner, it is possible to limit the current path in the lateral direction to the region between the p-type column layer and the bottom p-type layer. Therefore, according to this manufacturing method, a MOS transistor having an intermediate n-type layer and a low saturation current can be manufactured. Furthermore, according to this manufacturing method, the bottom p-type layer and the p-type column layer can be formed simultaneously, so that MOS transistors can be manufactured efficiently.

In a MOS transistor, the intermediate n-type layer may extend below a lower end of the bottom p-type layer.

For example, a corner portion between the side surface and the lower surface of the intermediate n-type layer may be formed by a curved surface that smoothly connects the side surface and the lower surface of the intermediate n-type layer. Each of the n-type column layers may be in contact with the corner portion of the corresponding intermediate n-type layer.

With this configuration, the electric field generated at the corner portion of the intermediate n-type layer can be reduced.

In a method of manufacturing a MOS transistor, in the etching of the side surface and the bottom surface of each of the trenches, the corner portion between the side surface and the bottom surface of each of the trenches may be etched so that the corner portion becomes a curved surface that smoothly connects the side surface and the bottom surface of each of the trenches.

Accordingly, the corner portion between the side surface and the bottom surface of each intermediate n-type layer are curved, so that the electric field generated at the corner portion can be reduced.

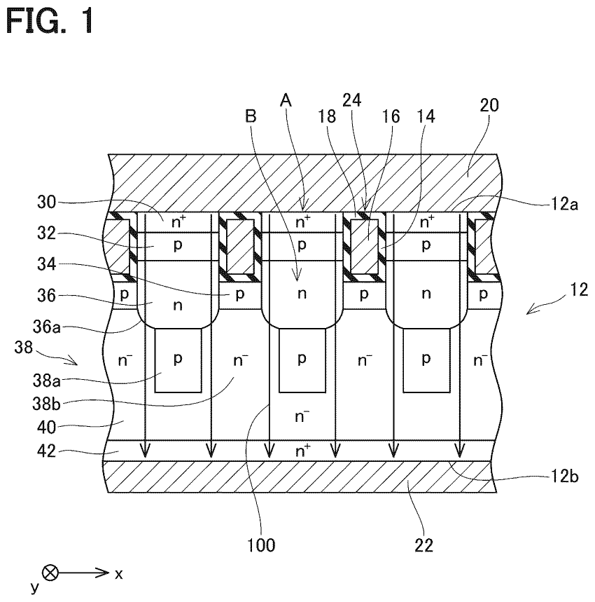

FIG. 1 shows a MOS transistor according to an embodiment. The MOS transistor of the embodiment is a metal-oxide-semiconductor field effect transistor (MOSFET). The MOS transistor includes a semiconductor substrate 12, a gate insulating film 14, a gate electrode 16, an interlayer insulating film 18, a source electrode 20, and a drain electrode 22. The semiconductor substrate 12 is made of SiC (that is, silicon carbide). The semiconductor substrate 12 has an upper surface 12a and a lower surface 12b. In the following description, a direction parallel to the upper surface 12a is referred to as x direction, and a direction parallel to the upper surface 12a and perpendicular to the x direction is referred to as y direction. Multiple trenches 24 are provided in the upper surface 12a of the semiconductor substrate 12. The trenches 24 are spaced apart from each other in the x direction. Each trench 24 extends linearly along the y direction on the upper surface 12a. The gate insulating film 14 covers an inner surface of each of the trenches 24. The gate electrode 16 is disposed in each of the trenches 24. The gate electrode 16 is insulated from the semiconductor substrate 12 by the gate insulating film 14. The interlayer insulating film 18 covers an upper surface of the gate electrode 16. The source electrode 20 covers the upper surface 12a of the semiconductor substrate 12 and the upper surface of the interlayer insulating film 18. The source electrode 20 is insulated from the gate electrodes 16 by the interlayer insulating films 18. The drain electrode 22 covers the lower surface 12b of the semiconductor substrate 12. In the following, a region between the two trenches 24 is referred to as an inter-trench region A.

The semiconductor substrate 12 has plural source layers 30, plural body layers 32, plural bottom p-type layers 34, plural intermediate n-type layers 36, a superjunction layer 38, a lower drift layer 40, and a drain layer 42.

Each source layer 30 is disposed in a corresponding inter-trench region A. Each source layer 30 is disposed in a range including the upper surface 12a of the semiconductor substrate 12. Each source layer 30 is in ohmic contact with the source electrode 20. Each source layer 30 is in contact with the gate insulating film 14 at the upper end of the side surface of the corresponding trench 24.

Each body layer 32 is disposed in a corresponding inter-trench region A. Each body layer 32 is disposed below the source layer 30. Each body layer 32 is in contact with the gate insulating film 14 on the side surface of the corresponding trench 24. Each body layer 32 is connected to the source electrode 20 by a p-type contact layer provided at a position not shown.

The bottom p-type layers 34 are spaced apart from each other in the x direction. Each bottom p-type layer 34 is disposed at a bottom of a corresponding trench 24. Each bottom p-type layer 34 is in contact with the gate insulating film 14 at a bottom surface of a corresponding trench 24. A gap between the two bottom p-type layers 34 is referred to as a gap region B.

Each intermediate n-type layer 36 is distributed across the inter-trench region A and the gap region B. Each intermediate n-type layer 36 extends from a position in contact with the lower surface of the body layer 32 to a depth below the lower end of the bottom p-type layer 34. There is no intermediate n-type layer 36 beneath the bottom p-type layer 34. Each intermediate n-type layer 36 is in contact with the gate insulating film 14 on the side surface of the corresponding trench 24. Each intermediate n-type layer 36 is in contact with the side surface of the bottom p-type layer 34 located on either side of the intermediate n-type layer 36. The intermediate n-type layer 36 has a corner portion 36a between the side surface and the bottom surface of each intermediate n-type layer 36. The corner portion 36a is formed by a curved surface that smoothly connects the side surface and the bottom surface.

The superjunction layer 38 is disposed beneath the bottom p-type layer 34 and the intermediate n-type layer 36. The superjunction layer 38 has p-type column layers 38a and n-type column layers 38b alternately arranged along the x direction.

Each p-type column layer 38a is disposed below the corresponding intermediate n-type layer 36 and is in contact with the corresponding intermediate n-type layer 36 from the lower side. The width of each p-type column layer 38a is narrower than the width of the intermediate n-type layer 36 above the p-type column layer 38a. Each p-type column layer 38a is in contact with the center of the intermediate n-type layer 36 above the p-type column layer 38a.

Each n-type column layer 38b is disposed below a corresponding bottom p-type layer 34. The width of each n-type column layer 38b is greater than the width of the bottom p-type layer 34 above the n-type column layer 38b. Each n-type column layer 38b is in contact with the bottom p-type layer 34 above the n-type column layer 38b and the intermediate n-type layers 36 on both sides of the bottom p-type layer 34 from the lower side. Each n-type column layer 38b is in contact with the entire lower surface of the bottom p-type layer 34 above the n-type column layer 38b. Each n-type column layer 38b is in contact with the corner portion 36a of the corresponding intermediate n-type layer 36 above the n-type column layer 38b.

The n-type impurity concentration of each intermediate n-type layer 36 is higher than the n-type impurity concentration of each n-type column layer 38b. For example, the n-type impurity concentration of each intermediate n-type layer 36 is 1.0×10¹⁷ cm⁻³ or more, and the n-type impurity concentration of each n-type column layer 38b is less than 1.0×10¹⁷ cm⁻³. Therefore, the boundary (such as the corner portion 36a) between the intermediate n-type layer 36 and the n-type column layer 38b has an n-type impurity concentration equal to 1.0×10¹⁷ cm⁻³.

The lower drift layer 40 is an n-type layer having the same n-type impurity concentration as each of the n-type column layers 38b. The lower drift layer 40 is disposed below the superjunction layer 38. The lower drift layer 40 is continuous with each of the n-type column layers 38b. The lower drift layer 40 is in contact with each of the p-type column layers 38a from the lower side.

The drain layer 42 is an n-type layer having a higher n-type impurity concentration than the lower drift layer 40. The drain layer 42 is disposed below the lower drift layer 40. The drain layer 42 is in contact with the lower drift layer 40 from the lower side. The drain layer 42 is in ohmic contact with the drain electrode 22 on the lower surface 12b of the semiconductor substrate 12.

Next, the operation of the MOS transistor will be described. The MOS transistor is used in a state where the MOS transistor is connected in series to a load (for example, a motor). A voltage is applied to the series circuit of the MOS transistor and the load. A voltage is applied to the MOS transistor in such a direction that the drain electrode 22 has a higher potential than the source electrode 20. The potential of the gate electrode 16 is controlled by a gate drive circuit (not shown).

When a potential equal to or higher than a gate threshold is applied to the gate electrode 16, a channel is formed in a region of each body layer 32 in the vicinity of the gate insulating film 14. The channel connects each of the source layer 30 to the intermediate n-type layer 36. Therefore, as indicated by an arrow 100 in FIG. 1, electrons flow from the source electrode 20 through the source layer 30, the channel, the intermediate n-type layer 36, the n-type column layer 38b, the lower drift layer 40, and the drain layer 42 to the drain electrode 22. That is, the MOS transistor is turned on. Since the intermediate n-type layer 36 having a higher n-type impurity concentration than the n-type column layer 38b is provided in each gap region B, the resistance of each gap region B is reduced. Therefore, electrons can flow through each narrow gap region B with low loss. As will be described later, each n-type column layer 38b is easily depleted when the MOS transistor is turned off, so that a sufficient breakdown voltage can be ensured even if the n-type impurity concentration of each n-type column layer 38b is high. Therefore, the n-type impurity concentration of each n-type column layer 38b is higher than that of the drift layer of a typical MOS transistor. This reduces the resistance of each n-type column layer 38b. Therefore, electrons can flow through each n-type column layer 38b with low loss. Therefore, the on-resistance of the MOS transistor is low.

When the potential of the gate electrode 16 is reduced to a potential lower than the gate threshold, the channel disappears and the MOS transistor is turned off. As a result, a depletion layer extends from each of the p-type column layers 38a to each of the n-type column layers 38b. Furthermore, since each bottom p-type layer 34 is in direct contact with the underlying n-type column layer 38b, a depletion layer extends from each bottom p-type layer 34 to each n-type column layer 38b. In this manner, since the depletion layer extends from not only the p-type column layer 38a but also the bottom p-type layer 34 to the n-type column layer 38b, the n-type column layer 38b is easily depleted. Therefore, the MOS transistor has a high breakdown voltage. In this manner, by adopting a structure in which each bottom p-type layer 34 is in direct contact with the underlying n-type column layer 38b, the breakdown voltage of the MOS transistor can be improved. Therefore, even if the n-type impurity concentration of each n-type column layer 38b is increased, a sufficient breakdown voltage can be obtained. Moreover, by increasing the n-type impurity concentration of each n-type column layer 38b, a low on-resistance can be achieved, as described above.

Furthermore, when the MOS transistor is turned off, not only the n-type column layers 38b but also the intermediate n-type layers 36 are depleted. If a bend exists at the boundary between the n-type column layer 38b and the intermediate n-type layer 36, an electric field is concentrated at the bend due to the influence of fixed charges (i.e., donors) in the depletion layer when the n-type column layer 38b and the intermediate n-type layer 36 are depleted. In contrast to this, according to this embodiment, the boundary between the n-type column layer 38b and the intermediate n-type layer 36 is formed by the corner portion 36a having a smoothly curved shape. Therefore, when each n-type column layer 38b and each intermediate n-type layer 36 are depleted, the electric field generated at the boundary is small. This further improves the breakdown voltage of the MOS transistor.

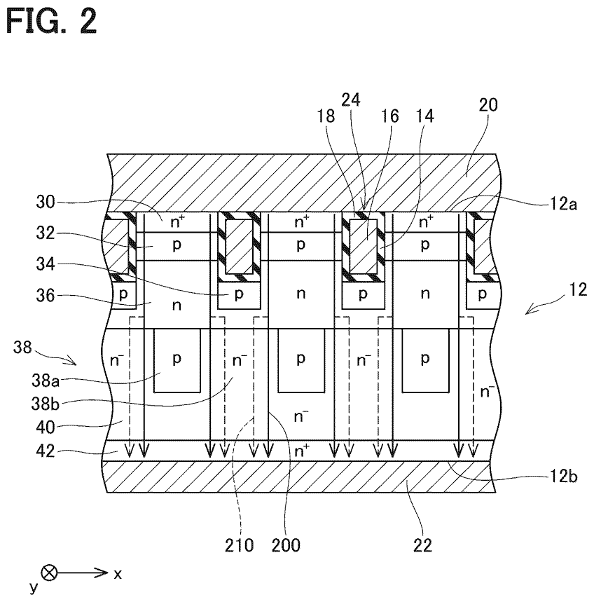

Next, a saturation current that flows through a MOS transistor when a load is short-circuited will be described while comparing a comparative example with the embodiment. FIG. 2 shows a MOS transistor of a comparative example. In the MOS transistor of the comparative example, the intermediate n-type layer 36 is distributed to the lower part of each bottom p-type layer 34, and the intermediate n-type layer 36 is in contact with the lower surface of each bottom p-type layer 34. Each n-type column layer 38b is separated from the bottom p-type layer 34 by the intermediate n-type layer 36. When the MOS transistor of the comparative example is turned on, electrons flow as indicated by the arrow 200 in FIG. 2. That is, in a normal on-state, the current path of the MOS transistor of the comparative example (i.e., the arrow 200 in FIG. 2) is narrow, similar to the current path of the MOS transistor of the embodiment (i.e., the arrow 100 in FIG. 1). When the load is short-circuited while the MOS transistor of the comparative example is in the on-state, an overvoltage is applied to the MOS transistor. Then, as indicated by the arrow 210 in FIG. 2, electrons diffuse laterally within the intermediate n-type layer 36 beneath each bottom p-type layer 34, Therefore, electrons flow as indicated by the arrows 200 and 210, and the width of the path through which the electrons flow becomes wider below the intermediate n-type layer 36. Therefore, in the MOS transistor of the comparative example, a high saturation current flows when the load is short-circuited.

In contrast, in the MOS transistor of the embodiment, since there is no intermediate n-type layer 36 below each bottom p-type layer 34, electrons are less likely to diffuse laterally below each bottom p-type layer 34 when the load is short-circuited. For this reason, as indicated by the arrow 100 in FIG. 1, even when the load is short-circuited, the width of the path through which electrons flow is narrow, just as in normal times. That is, even when the load is short-circuited, the main path through which electrons flow is limited to the region between the bottom p-type layer 34 and the p-type column layer 38a in the x direction. Therefore, in the MOS transistor of the embodiment, the saturation current that flows when the load is short-circuited is low. As described above, the structure of the MOS transistor according to the embodiment can reduce the saturation current.

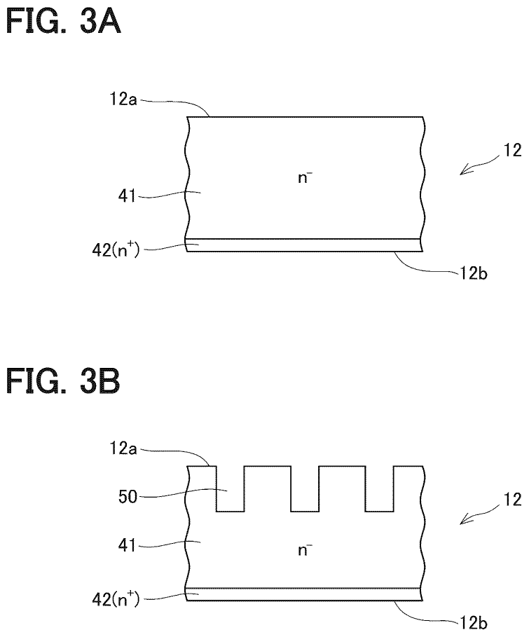

Next, a method of manufacturing the MOS transistor according to the embodiment will be described. First, as shown in FIG. 3A, a reference n-type layer 41 is formed on a drain layer 42 by epitaxial growth. The reference n-type layer 41 is an n-type layer having the same n-type impurity concentration as each of the n-type column layers 38b and the lower drift layer 40. In this state, the reference n-type layer 41 is exposed at the upper surface 12a of the semiconductor substrate 12. Next, as shown in FIG. 3B, the upper surface 12a of the semiconductor substrate 12 is selectively etched by anisotropic etching to form the grooves 50 in the upper surface 12a. Here, the grooves 50 are formed at interval in the x direction.

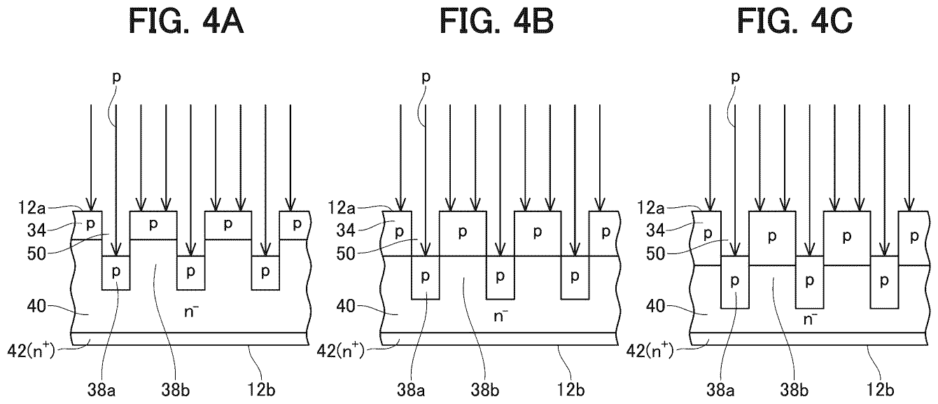

Next, as shown in FIG. 4A, p-type impurities are implanted into the semiconductor substrate 12 from the upper side. As a result, the bottom p-type layer 34 is formed in the area exposed at the upper surface 12a, and the p-type column layer 38a is formed in the area exposed at the bottom of the groove 50. The reference n-type layer 41 remaining between the p-type column layers 38a becomes the n-type column layer 38b. The reference n-type layer 41 remaining below the p-type column layer 38a becomes the lower drift layer 40.

FIG. 4A shows, as an example, a case where the implantation depth of the p-type impurity is shallower than the depth of the groove 50. However, as shown in FIG. 4B, the implantation depth of the p-type impurity may be equal to the depth of the groove 50 or may be deeper than the depth of the groove 50 as shown in FIG. 4C. In the case of FIG. 4C, the bottom p-type layer 34 and the p-type column layer 38a are formed so as to be connected to each other.

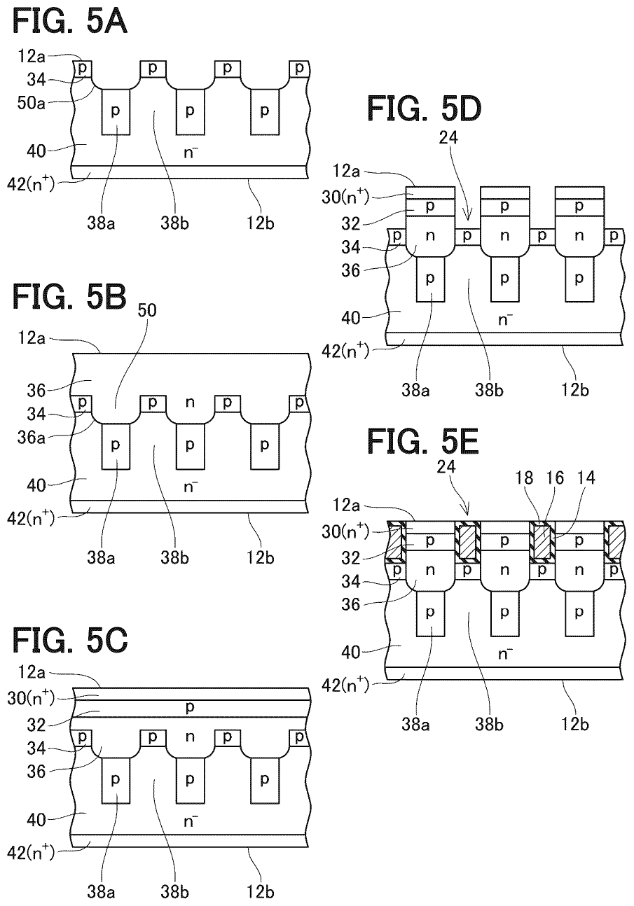

Next, as shown in FIG. 5A, the upper surface 12a and the inner surface of the groove 50 (that is, the side surface and the bottom surface of the trench where the p-type column layer is located at the bottom) are etched by isotropic etching. This increases the width of the groove 50. When the bottom p-type layer 34 and the p-type column layer 38a are connected as shown in FIG. 4C, the bottom p-type layer 34 and the p-type column layer 38a are separated by etching the grooves 50. Furthermore, by etching the inner surface of the groove 50, the corner portion 50a of the groove 50 becomes a curved surface that smoothly connects the side surfaces and the bottom surface.

Next, as shown in FIG. 5B, the intermediate n-type layer 36 is epitaxially grown on the upper surface of the semiconductor substrate 12. The n-type impurity concentration of the intermediate n-type layer 36 is higher than the n-type impurity concentration of the reference n-type layer 41 (that is, the n-type column layer 38b and the lower drift layer 40). The intermediate n-type layer 36 is epitaxially grown so that each groove 50 is filled with the intermediate n-type layer 36. Therefore, in each groove 50, the corner portion 36a between the side surface and the bottom surface of the intermediate n-type layer 36 forms a smoothly curved surface. The intermediate n-type layer 36 is in contact with each p-type column layer 38a at the center of the bottom surface of each groove 50, and in contact with each n-type column layer 38b at the corner portion 36a. After the intermediate n-type layer 36 is formed, the surface of the intermediate n-type layer 36 (i.e., the upper surface 12a) is planarized by CMP (Chemical Mechanical Polishing).

Next, ion implantation is performed on the upper surface 12a of the semiconductor substrate 12 to form the body layer 32 and the source layer 30 on the intermediate n-type layer 36, as shown in FIG. 5C.

Next, as shown in FIG. 5D, the upper surface 12a of the semiconductor substrate 12 is selectively etched by anisotropic etching to form the trenches 24 in the upper surface 12a. The trenches 24 are formed at interval in the x direction. The trench 24 is formed in the upper portion of the bottom p-type layer 34 to penetrate the source layer 30, the body layer 32 and the intermediate n-type layer 36 and to reach the bottom p-type layer 34. Therefore, the bottom p-type layer 34 is exposed at the bottom surface of each trench 24.

Next, as shown in FIG. 5E, the gate insulating film 14 is formed to cover the inner surface of each trench 24. Next, the gate electrode 16 made of polysilicon is formed in each of the trenches 24. Next, the interlayer insulating film 18 is formed on the gate electrode 16. Thereafter, the source electrode 20 is formed to cover the upper surface 12a, and the drain electrode 22 is formed to cover the lower surface 12b. This completes the MOS transistor shown in FIG. 1.

According to this manufacturing method, the bottom p-type layer 34 and the p-type column layer 38a can be formed simultaneously by ion implantation, so that the MOS transistor can be manufactured efficiently. Furthermore, according to this manufacturing method, the corner portion 36a of each intermediate n-type layer 36 can be formed into a curved shape, making it possible to suppress the concentration of electric field.

Although the embodiment has been described in detail above, these are merely examples and do not limit the scope of present disclosure. The techniques described in claims include various modifications of the specific examples illustrated above. The technical elements described in the present specification or the drawings exhibit technical usefulness alone or in various combinations, and are not limited to the combinations described in the claims at the time of filing. In addition, the techniques illustrated in the present specification or drawings achieve plural objectives at the same time, and achieving one of the objectives itself has technical usefulness.

What is claimed is:

1. A MOS transistor comprising:
a semiconductor substrate having an upper surface in which a plurality of trenches is provided; and
a gate insulating film and a gate electrode disposed in each of the trenches, wherein
the semiconductor substrate includes:
a plurality of bottom p-type layers arranged in a predetermined direction intersecting the trenches, each of the bottom p-type layers being in contact with the gate insulating film at a bottom surface of the trench;
a plurality of intermediate n-type layers respectively disposed within intervals of the plurality of bottom p-type layers; and
a superjunction layer arranged below the bottom p-type layers and having p-type column layers and n-type column layers alternately arranged in the predetermined direction,
an n-type impurity concentration of the intermediate n-type layer is higher than an n-type impurity concentration of the n-type column layer,
each of the p-type column layers is in contact with the intermediate n-type layer from a lower side, and
each of the n-type column layers is in contact with the bottom p-type layer and the intermediate n-type layers located on both sides of the bottom p-type layer from a lower side.

2. The MOS transistor according to claim 1, wherein the intermediate n-type layer extends to a position below a lower end of the bottom p-type layer.

3. The MOS transistor according to claim 2, wherein
the intermediate n-type layer has a corner portion between a side surface and a lower surface of the intermediate n-type layer,
the corner portion is formed by a curved surface that smoothly connects the side surface and the lower surface of the intermediate n-type layer, and
each of the n-type column layers is in contact with the corner portion of the intermediate n-type layer.

4. A method of manufacturing a MOS transistor comprising:
forming a plurality of grooves at an interval in a predetermined direction on an upper surface of a semiconductor substrate from which a reference n-type layer is exposed;
implanting a p-type impurity into the upper surface and a bottom of each of the grooves to form a bottom p-type layer within an area exposed at the upper surface and a p-type column layer within an area exposed at the bottom of each of the grooves;
etching a side surface and a bottom surface of each of the grooves where the p-type column layer is located at the bottom;
epitaxially growing an intermediate n-type layer on the upper surface such that each of the grooves is filled with the intermediate n-type layer, the intermediate n-type layer having a higher n-type impurity concentration than the reference n-type layer;
forming a plurality of trenches at an interval in the predetermined direction on the upper surface of the semiconductor substrate such that the bottom p-type layer is exposed at the bottom surface of each of the trenches; and
forming a gate insulating film and a gate electrode in each of the trenches.

5. The method according to claim 4, wherein in the etching of the side surface and the bottom surface of each of the grooves, a corner portion between the side surface and the bottom surface of each of the grooves is etched such that the corner portion becomes a curved surface that smoothly connects the side surface and the bottom surface of each of the grooves.
